(19) United States
(12) Patent Application Publication
(10) Pub. No.: US 2026/0228877 A1
(43) Pub. Date: Aug. 6, 2026

(54) FULL WAFER METROLOGY

(71) Applicant: NOVA LTD., Rehovot (IL)

(72) Inventors: Doron Avraham, Rehovot (IL); Alex Shichtman, Rehovot (IL); Michael Mehanik, Rehovot (IL); Roi RINGEL, Rehovot (IL); Shahar Bassan, Rehovot (IL); Shimon YALOV, Rehovot (IL); Michael Panich, Rehovot (IL); Amir Len, Rehovot (IL); Shachar PAZ, Rehovot (IL); Nir Kampel, Rehovot (IL); Nachshon Daskal, Rehovot (IL); Gilad Barak, Rehovot (IL)

(73) Assignee: NOVA LTD., Rehovot (IL)

(21) Appl. No.: 19/154,763

(22) PCT Filed: Feb. 7, 2024
(86) PCT No.: PCT/IB2024/051139

§ 371 Date: Aug. 7, 2025

Related U.S. Application Data
(60) Provisional application No. 63/483,960, filed on Feb. 8, 2023.

(51) Int. Cl. G06T 7/00; G01N 21/88; G01N 21/95; H04N 23/695

(52) U.S. Cl. CPC G06T 7/0004; G01N 21/8851; G01N 21/9501; H04N 23/695; G06T 2207/30148

(57) ABSTRACT

A method for operating an integrated evaluation system, the method includes (i) introducing, by a motion system, a relative movement between a sample, and at least one head of a IM head or an IIU head, (ii) performing by the IM head, measurements of a group of measurement sites of the sample; (iii) acquiring, by the IIU head, images of regions of the sample that include the measurement sites; (iv) receiving, by a processing circuit, the measurements of the group and the images of the regions; and (v) using a mapping between the measurements and the pixels of the images that correspond to the measurement sites, to estimate measurement values that are within the regions and outside the measurement sites.

### CROSS REFERENCE

This application claims priority from U.S. provisional patent Ser. No. 63/483,960 filing date Feb. 8, 2023, which is incorporated herein by reference.

### BACKGROUND

Semiconductor process control is based on extensive, high-end characterization solutions. Optical metrology technologies are of special value, offering fast, non-destructive solutions.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A-1F illustrate examples of integration schemes;

FIG. 2 illustrates an example of regions and measurement sites;

FIG. 3 illustrates an example of images, measurements, a mapping and evaluated measurements;

FIG. 4 illustrates an example of a method; and

FIGS. 5-7 illustrate examples of integrations.

### DETAILED DESCRIPTION OF THE DRAWINGS

Of special interest for the current invention is integrated metrology (IM)—a metrology approach by which the metrology tool is attached to the fabrication process tool, offering the potential to measure the processed wafer immediately before and/or after processing. The fast feedback (‘Time to Measurement’) offered by IM is crucial for process control of such techniques as Chemical Mechanical Planarization (CMP), where Advanced Process Control (APC) protocols use the swift metrology feedback to keep the process within required margins. IM typically provides dimensional information characterizing the fabricated nanostructures at a few points on the wafer, from which processing information can be derived.

IM metrology provides accurate but sparse metrology across the wafer, namely—few tens of points at most. An IM tool provides the value of some Parameter Of Interest (POI) or few POIs, characteristic of the measured structure. Typical POIs are layer thicknesses and structural dimensions.

Extending this characterization across the entire wafer is typically done by interpolation\extrapolation algorithms. However, such approaches suffer from very significant errors when across-wafer variations are not exceedingly smooth, and (for example) are not able to identify excursions taking place between the measured points and at the wafer edge.

With the increasingly stringent process margins, the required feedback from the metrology is becoming progressively more elaborate. One common requirement is for significantly increasing the number of characterized sites—to provide higher resolution coverage of the processed wafer. However, simply increasing the number of points across the wafer would require significantly longer measurements, incompatible with the high throughput (TPT) requirements from the metrology solutions. Conversely, simplified solutions-such as low-resolution full-wafer imaging-lack the detailed information and sensitivity required to analyze the complicated measured nanostructures.

The goal of the current invention is to extend the high-end metrology offered by IM to massive across-wafer characterization. Instead of sporadic information on a few sites, metrology will be provided on many (possibly hundreds or thousands) sites across the wafer. Below we term this capability as ‘POI mapping’. However, this extension will come at minimal expense of metrology quality, by joining information from high-end IM with areal-coverage imaging channel combined into the same metrology platform.

Current solutions span a range of metrology approaches, offering varying degrees of metrology quality and time-to-measurement. These include:
a. In-situ\‘end-point’ detectors: metrology modules integrated inside the processing tool and offering feedback during processing. Such low-end solutions cannot be directed to measuring specific locations, suffer from poor control over measurement conditions and measurement quality and are used for rough process control. These solutions are not able to provide the high-quality feedback offered by methods detailed below and by the method described in this invention.
b. Integrated metrology (IM): these tools are typically based on broadband optical scatterometry, providing Optical Critical Dimensions (OCD) on selected metrology sites. As described above, IM solutions are highly useful in fast time-to-measurement process control but can only offer feedback on a limited number of sites across the wafer (several tens of sites at most).
c. Full-wafer imaging: in these solutions, a full image of the wafer is taken. This massive data collection comes at the expense of information quality, as each position is only measured by one or a few wavelengths and often the spatial resolution is poor. High-end full wafer metrology solutions exist, which are very expensive and only available as stand-alone metrology stations, and as such cannot offer fast time to metrology.

None of these solutions combines the high-end metrology quality offered by optical scatterometry with extensive aerial coverage.

The goal of the current invention is to extend the high-end metrology offered by IM to massive across-wafer characterization. Instead of sporadic information on a few sites, metrology will be provided on many (possibly hundreds or thousands) sites across the wafer. Below we term this capability as ‘POI mapping’. However, this extension will come at minimal expense of metrology quality, by joining information from high-end IM with areal-coverage imaging channel combined into the same metrology platform.

The goal behind the current invention is an extensive (up to full wafer) metrology solution at quality comparable to that offered by high-end IM. This is accomplished by a HW implementation combining both IM measurement capability and an Integrated Imaging Unit (IIU) offering large coverage of significant portions of the measured wafer at few spectral bandwidths. In order to achieve such a goal, a combination of HW implementation, measurement protocol and specific interpretation algorithms are involved. The invention is based on the following key ingredients:

An IM metrology platform offering OCD metrology on a few sites across the wafer (as commonly done by IM). This set of measurements is used for two goals:
a. Metrology anchor: the measured POI values at the points where IM is conducted serve as ‘known’ points. The POI mapping (i.e. the eventual deduced POI values across the entire imaged domain) will necessarily have the corresponding values at the IM measured points.
b. POI training: the same points measured using IM are also measured by the IIU (or at least a large fraction of them). A dedicated algorithm is used to identify the underlying relation between the IIU data and the IM POI interpretation.

An integrated imaging unit (IIU) combined onto the same platform, offering large coverage of significant portions of the measured wafer at few spectral bandwidths.

A measurement protocol by which both measurement modules (OCD and IIU) provide their part of the metrology with minimal impact on the overall wafer characterization time (compared to standard IM performance).

An algorithmic suite allowing the combination of IM and IIU information. The end result of this analysis engine is an extension of the IM measured data to all regions covered by the IIU.

Below we describe and detail the unique attributes of each of these ingredients. It should be stressed that the current invention relies on the combined functionality of all these ingredients together.

### IM Metrology Platform and Integrated Imaging Unit

Integrated metrology platforms are strictly confined in their footprint, due to limitations imposed by their integration onto the host process tool. These must be satisfied in the current invention, imposing a significant challenge in integrating both the OCD and IIU units without breaching dimensional limitations.

For clarity, we first introduce the basic ingredients involved in an IM unit:

An IM tool is connected to a process tool (e.g. CMP platform). A robotic arm transfers wafers between the process tool and the measurement unit (MU). Below, we use the term MU to denote the entire metrology tool, including both IM and IIU.

Inside the IM tool, a measurement head directs light onto a specific location on the wafer and collects scattered light. The same measurement head can also include an imaging channel providing images of the measured region.

Due to footprint restrictions, lateral motion of the wafer is significantly limited. In order to allow the measurement head to reach all desired points across the wafer, commonly the measurement head is moved above the wafer or both measurement head and wafer are moved.

Here are presented several possible implementations allowing the required integration of both IM and IIU for the current invention:

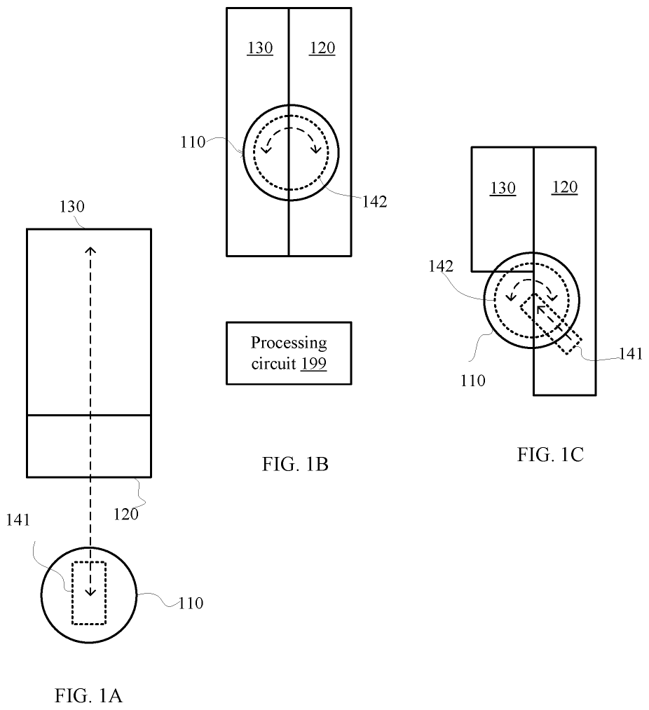

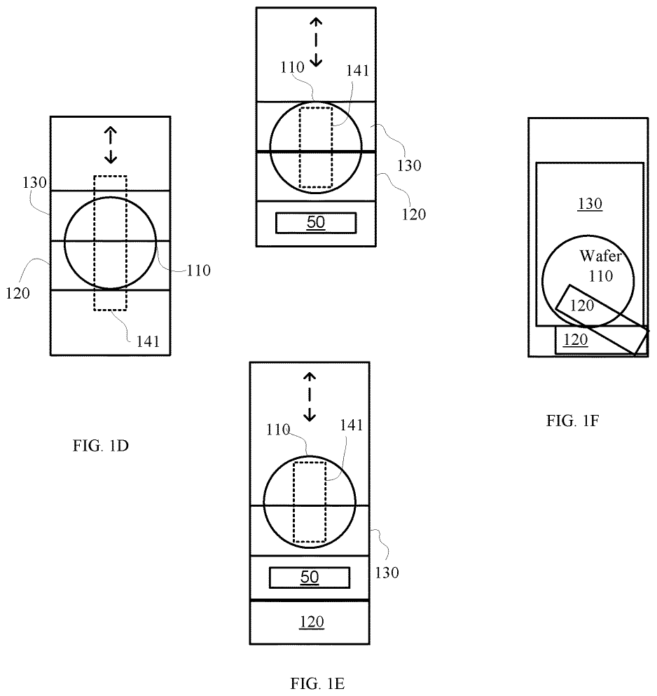

IIU scanning during wafer load\unload process: in this embodiment, the imaging module is placed above the wafer entry port to the IM unit and images the wafer as it is transferred between the IM tool and the process tool by the tool robot. Such implementation was discussed in detail in PCT patent application publication WO 2022/043935 A1. Such an approach allows minimal (virtually no) impact on the overall metrology throughput (TPT). However, imaging is performed in a highly uncontrolled manner—with wafer motion and vertical position controlled by the robot and moving at very high velocities and accelerations. Consequently, the expected imaging quality is poor, limiting the overall resulting performance and useability for high-end applications. Furthermore, the IIU module in such an embodiment is extremely constrained in its allowed volume due to space restrictions required from the metrology integration, further limiting its achievable quality. See, for example, FIGS. 1A and 6-8.

Measurement unit partition: in some embodiments, it is possible to restrict the space used for IM metrology to one part of the MU while still allowing full coverage of the wafer. This can be implemented by controlling both the IM measurement head above the wafer and the wafer itself. For example:
a. The wafer can be placed on a rotating stage, a moving IM measurement head allowing scan of half of the wafer area, and a 180° rotation of the stage allowing coverage of the second wafer half. See, for example, FIG. 1B.
b. The IM measurement head can be placed on a moving stage covering a radial path across the wafer, and the wafer rotated to allow full-wafer metrology coverage.
c. The IM measurement head can be static and the wafer moving in one direction. The wafer lateral motion places the IM measurement head at a chosen radial location, and rotation of the wafer provides full wafer coverage (R-θ configuration). See, for example, FIG. 1C.

Importantly, such implementations can allow significant available space above the wafer to be used for additional metrology equipment. In the current invention, this space will be used for the placement of the IIU module.

It should be noted that in some of these implementations it is not trivially possible for both IM and IIU modules to cover the entire wafer area. For example, if the MU is split so that IM and IIU each cover half of the wafer, some buffer area will be required between these modules (e.g.) to guarantee no collision takes place between moving elements. Mitigations to this challenge can include another motor allowing lateral transition of the wafer or advanced synchronization between the two measurement heads to guarantee no such collision takes place.

Ride-along integration: for implementations when the optical heads are moving, the most challenging aspect of integrating both IM and IIU measurements in the same enclosure is arguably the joint motion of these two modules. Motors and holding mechanics have to be scanned across the wafer surface without collision and satisfying volume limitations.

A mitigation to this possibility involves assembling both IM and IIU modules on the same moving module. See, for example, FIG. 1D. This approach utilizes the same motion assembly, it greatly simplifies integration and measurement sequence. However, such integration has a negative impact on the obtained TPT, as the measurement head has to run sequentially over all IM sites and the full IIU scan. Furthermore, as the measurement head is made significantly heavier, this approach has the downside of reduced measurement speed even for the IM sites alone.

Some mitigation to the negative TPT implications suffered by this approach is possible if partial IIU coverage is allowed: it is possible to limit the images domains across the wafer only to those which are already covered by the measurement head during its travel between IM sites.

Mitigation to the throughput hit of this approach involves a detachable IIU unit: the IM measurement head can run a measurement sequence with the IIU head placed at some designated location inside the enclosure. When IIU measurement is to be run, the measurement head travels to the IIU head location, picks it up and runs the measurement. Conversely, the IIU head can replace the IM measurement head at such exchange. See, for example, FIG. 1E that illustrates a movement of the IIU head only or a movement of both heads.

Flexible scheme: by placing the IIU unit above the entry port to the measurement unit, it is guaranteed that the wafer passes under it during loading by the robot (and taken out during unloading). Imaging can be done during one (or both) of these steps by the IIU—similarly to the external integration option described above. As stated, such imaging will suffer from poor control over the wafer speed and positioning, reducing the imaging quality, but could be sufficient for some cases. When higher-quality imaging is required, the same IIU can be carried across the wafer (e.g. using a ‘ride-along’ integration).

Partial wafer coverage: significant simplification to this integration challenge may be provided by limiting the IIU measurement to partial coverage of the wafer area. The IIU module can be made significantly smaller and integrated on vacant volume of the measurement unit.

Specifically, the IIU module can be placed on a moving motor. When IIU measurements are to be taken, the motor will place it above the wafer. When IM measurements are to be taken the IIU module will be retracted, allowing free motion of the IM measurement head above the wafer. See, for example FIG. 1F.

In FIGS. 1A-1F the following reference numbers were used: wafer 110, IIU head 120, IM head 130, linear mechanical stage 141, rotational mechanical stage 142, and selector 50 for selecting which head(s) to attached to a mechanical stage.

It is possible to use time allocated for other functionalities to obtain the IIU measurements. For example, typically a ‘notch-finding’ sequence is run before any IM measurement, by which the wafer is rotated and a notch places at the wafer edge is located to correctly set the wafer orientation. It is possible to use the IIU measurement (e.g. covering some range from the wafer rim and towards its center) during these rotations and obtain large area coverage at no TPT hit.

The IIU module can be based on various design concepts. Generally, implementations will include the following key ingredients:
a. Illumination: preferably allowing several different bandwidths at high intensity and high illumination stability, so as to provide high signal-to-noise even at short acquisitions. Illumination can be based on strobe or continuous sources.
b. Optical apparatus: leading light from the light source to the wafer and back towards the detection system. The optics can include auto-focus mechanism, but if implemented with large enough depth of focus could also be devoid of such mechanism (reducing cost and complexity). In the current implementation, telecentric low-NA implementations are preferred, so as to allow limited-aberration large-field imaging.
c. Detection: various detectors can be implemented, including CCD, CMOS and TDI-based cameras. Choice of preferred detector would depend on other system attributes, required specs and mode of use of the module.

As the specific implementation details are of secondary importance in regard to this invention, they will not be further elaborated here.

### Dual-Coverage Metrology Protocol

The basic required measurement sequence involves both IM and IIU measurements of the wafer. Several implementation possibilities offer different advantages and limitations:
a. Independent flows: in this approach, the IM and IIU measurements are run independently. For example, the IM measurements can be taken at the standard IM sampling plan. The IIU will either cover the entire wafer or regions of increased interest-depending on its speed.
b. ‘IM first’: In this flow, the IM metrology is used in order to identify suspected areas of the wafer where denser metrology coverage is of interest. For example, a trend in the POI values can be identified, pointing to some regions in the wafer edge where POI is at risk of reaching the process window limitations. IIU measurements will be taken at areas prioritized by this first measurement sequence.
c. ‘IIU first’: First, a large-area IIU measurement is collected. An algorithmic analysis then identifies how the fabricated structural characteristics vary across the wafer. IM sampling plan is adapted based on these inputs, investing in denser measurements at regions where large variations are observed or where some suspicions of POI excursions are reached.
d. IM first and last: a first IM sampling is obtained, followed by an IIU measurement. The IIU measurement can be dictated by the IM measurement (as in ‘IM first’ scheme) or not. Based on these two datasets, the algorithmic interpretation layer (described in more detail below) creates the detailed POI map across the entire IIU measured area. Using this map, abnormal POI values or suspected regions can be identified-sending the IM metrology for additional, denser measurements. This process can take place multiple times, providing increasingly accurate and dense measurements at the most critical regions across the wafer.

### Algorithmic Data-Fusion Solution

Combining the information from IM and IIU is a highly non-trivial task, as the two datasets offer very different sensitivities. However, modern algorithms, commonly utilizing machine-learning approaches, offer remarkable potential in such tasks. The proposed algorithmic approach is based on the following structure.

Interpretations of the IM measurements can be done as commonly today, separated from the unique challenge at hand. While this is the simplest embodiment, alternative approaches are discussed below.

Interpretation of the IIU data and large-area analysis:
a. A semiconductor wafer is comprised of an array of identical-design regions termed ‘fields. Inside each field there could be several sub-regions of identical design called ‘dies’ which are eventually diced and packaged to create the desired semiconductor chips. These dies are separated by thin regions called ‘scribe lines. Scribe lines are eventually cut to separate individual dies, but during fabrication they hold multiple test structures used for metrology and process control.
b. Metrology is typically conducted on dedicated metrology sites in the scribe lines. On some cases (more often in memory-device applications) some metrology can be conducted on periodic regions inside the die. Regardless of the specific measurement location, an IM measurement provides information characteristic of the field (or die) where it was measured. Put differently, IM metrology of field i involves a set of measured spectra

$${\vec{A}}^{( i )} = [ {S}_{1}^{( i )} ( λ ) , {S}_{2}^{( i )} ( λ ) … ] .$$

Different spectra S(λ) can stand for different metrology channels (polarizations, azimuths, angles of incidence) and different metrology sites related to the same field. Typically, few such spectra are collected per field, each holding roughly a thousand different wavelengths.
c. A IIU measurement is similarly split into datasets related to different fields on the wafer. For each field i, the IIU measurement can be represented by

$${\vec{B}}^{( i )} = [ {M}_{1}^{( i )} ( x ) , {M}_{2}^{( i )} ( x ) … ] .$$

Here, M(x) represents the field image at point x and x standing for the multitude of image pixels covering the field; multiple images can be taken at different spectral bandwidths, polarizations etc.
d. The IM interpretation process provides the relation between the measured \vec{A}⁽ⁱ⁾ and the relevant POI values P⁽ⁱ⁾. From this result, an association is obtained between the IIU measurement \vec{B}⁽ⁱ⁾ and the same POI values P⁽ⁱ⁾.
e. With this association, it is possible to identify a translation between the IIU readout and the POI values. We shall term this relation the ‘immediate training’.
f. The immediate training is then applied to all fields measured by the IIU, providing POI values across a large portion of the wafer (or its entirety).

While this basic rationale serves as the core principle behind the current invention, several elaborations are possible for it:
a. Initial training session: the described approach is based on identifying a relation between the full-field IIU measurement and the corresponding POI values as provided by the IM. However, identifying this relation based on the limited dataset provided by an IM measurement across one wafer may not be reliable and robust enough.
b. The training protocol can be extended by adding a preliminary stage during which several wafers are measured using both IM and IIU and an algorithmic analysis identifies the relation between them. The result of this stage will then improve and stabilize the ‘immediate training’ step conducted later on. Various algorithmic approaches are known to address such tasks, such as ‘dimension reduction’, ‘transfer learning’ and many more.
c. Reliance on ‘up-sampling’ scheme: another approach for the extension of IM measurements to full-wafer metrology was proposed in U.S. Pat. No. 11,093,840 and US Prov. PA, No. 63/328,332 and termed either “Sampling Enhancement” or ‘up-sampling’. There, an extensive preliminary process based on IM measurement of multiple wafers is used for the training of a machine-learning based solution, by which some extension of the IM results to full wafer is made possible. The method proposed in the current invention can rely on ‘up-sampling’ results as a first guess and guidance, significantly improving upon its results using the additional information provided by the IIU. In addition, it could significantly simplify the preliminary training process, requiring significantly less samples for training.

The joint integration of the IM and IIU module offers several potential benefits:
a. As described, the key offered benefit relates to extending the IM measurement to large portions of the wafer or its entirety, ideally providing IM-grade feedback to all fields on the wafer.
b. Residue detection: another potential benefit relates to identifying material residues through the IIU imaging. Combining such capability along with IM metrology has significant benefit for various process control steps. For example, in CMP uses, this could augment the metrology solution with the ability of identifying incomplete removal of a polished layer.
c. Macro-scratch and macro-defect detection: the IIU could allow identification of large scratches and defects created on the wafer during processing.
d. Such identification can be based on various algorithmic approaches, borrowed from the field of defect inspection.
e. While the optical quality of the IIU module will not allow identification of small-scale defects and submicron scratches, it could be used for identifying large scale imperfections.
f. Specific variations of the optical implementation—such as dark-field imaging, crossed-polarization imaging etc.—could be of significant advantage to such metrology and may be included in the IIU implementation.
g. System health monitoring: one concern with using IM metrology relates to particles falling from the measurement system onto the wafer surface, damaging the fabricated devices. A common solution to this problem is the addition of a transparent window between the optical layer and the measured wafers. However, with time, particles may fall and accumulate on the window surface, leading to adverse effects on the metrology quality at their corresponding locations. This is typically solved by periodically cleaning or replacing the window-a process which has cost and tool-availability penalties, and conversely may not be frequent enough to guarantee measurement quality. The IIU could be used to map the window surface, identifying such degradation of transparency due to accumulated particles. Possibly, a focusing mechanism may be added allowing the IIU module to image the window surface.
h. Notch-finding by IIU: during wafer introduction into the IM enclosure, the wafer is typically first rotated and aligned to the measurement system. This alignment is often done by identification of a notch residing at the wafer edge on a specific location. The identification of this notch (a process termed ‘notch-finding’) can be implemented in various ways. The IIU can be used for such a goal, replacing other HW targeting the same goal. Furthermore, during wafer rotation for notch-finding, the IIU can collect measurements of the wafer surface, providing imaging metrology with no TPT penalty.

In any of the mentioned above configuration there is a processing circuit-denoted 199 in FIG. 1B. The processing circuit may be implemented as a central processing unit (CPU), and/or one or more other integrated circuits such as application-specific integrated circuits (ASICs), field programmable gate arrays (FPGAs), full-custom integrated circuits, etc., or a combination of such integrated circuits.

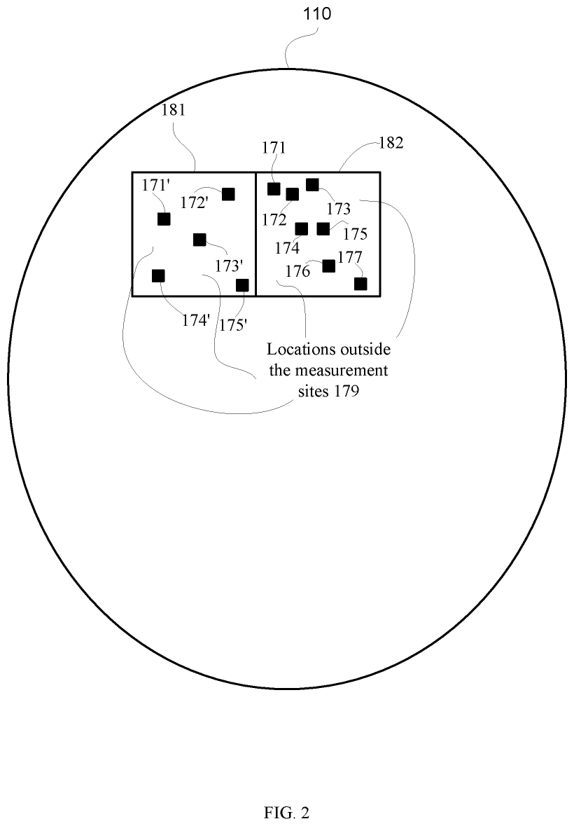

FIG. 2 illustrates a wafer 110, a first region 181, a second region 182, measurement sites 171′-175′ within the first region, measurement sites 171-177 within the second region, and locations outside the measurement sites 179 (within the first and/or second region). The IIU head acquired an image of the first region and an image of the second region. The IM head performed measurements of the mentioned above measurement sites.

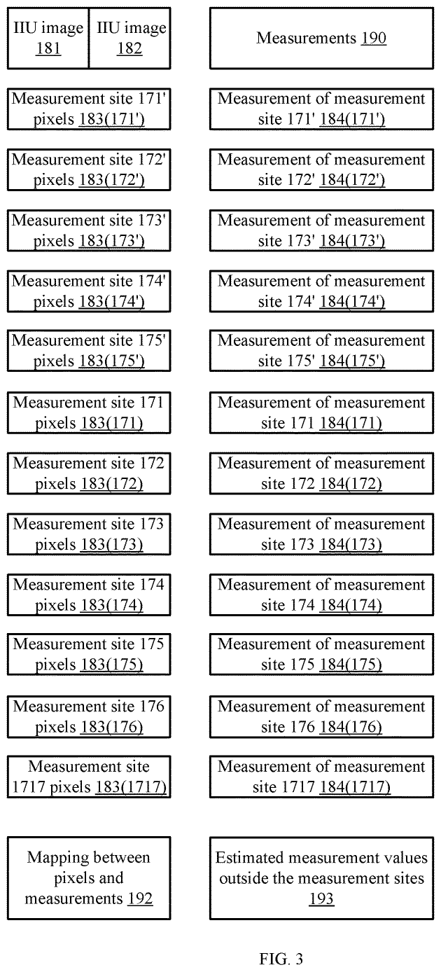

FIG. 3 illustrates first and second images (of the first and second regions)—denoted IIU image 181 and IIU image 182, measurements 190 of the measurement sites—that include measurements 184(171′)-184(175′) and 184(171)-184(177), the measurement sites are included in the first and/or second images and their pixels within the first and/or second image are denoted 183(171′)-183(175′) and 183(171)-183(177) respectively, a mapping between pixels and measurements 192 and estimated measurement values outside the measurement sites 193.

Measurements and pixels related to the same measurement sites may be used to train and/or retrain and/or adjust and/or test the mapping.

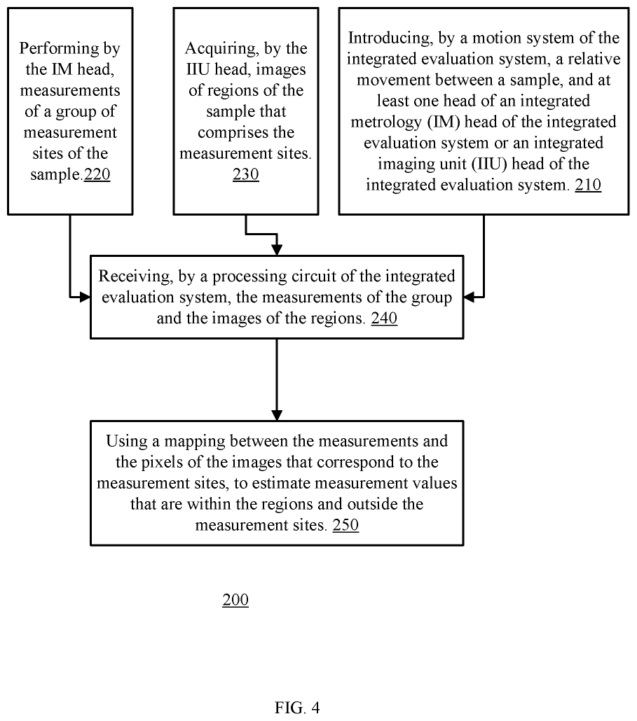

FIG. 4 illustrates method 200 for operating an integrated evaluation system.

According to an embodiment, method 200 includes step 210 of introducing, by a motion system of the integrated evaluation system, a relative movement between a sample, and at least one head of an integrated metrology (IM) head of the integrated evaluation system or an integrated imaging unit (IIU) head of the integrated evaluation system.

According to an embodiment, method 200 includes step 220 of performing by the IM head, measurements of a group of measurement sites of the sample.

According to an embodiment, method 200 includes step 230 of acquiring, by the IIU head, images of regions of the sample that comprises the measurement sites; wherein an aggregate area of the regions of the samples exceeds an aggregate area of the measurement sites.

Step 220 may be followed by step 230, may be preceded by step 230 or may be executed (at least in part) in parallel to step 230.

Step 220 may be executed based on an outcome of step 230 or may be executed regardless of the outcome of step 230.

Step 230 may be executed based on an outcome of step 220 or may be executed regardless of the outcome of step 220.

According to an embodiment, method 200 includes determining, by a processing circuit, regions to be imaged during step 230 based on the measurements of the group acquired during step 220. And step 230 includes acquiring by the IIU head the images of the regions following the determination of the regions.

According to an embodiment, method 200 includes determining by the processing circuit the measurement sites to be measured during step 220 based on images of the regions acquired during step 230. And step 220 includes performing by the IM head the measurements of the group following the determination of the regions.

Step 210 may be executed in any timing relationship to an execution of step 220 and/or step 230. A relative movement may be introduced before the execution of step 220, before the execution of step 230, between the execution of step 220 and the execution of step 230, between the execution of step 230 and the execution of step 220, at least partially overlapping the execution of step 220, at least partially overlapping the execution of step 230, and/or following the execution of at least one step of step 220 and step 230.

According to an embodiment, steps 220 and 230 are followed by step 240 of receiving, by a processing circuit of the integrated evaluation system, the measurements of the group and the images of the regions.

According to an embodiment, step 240 is followed by step 250 of using a mapping between the measurements and the pixels of the images that correspond to the measurement sites, to estimate measurement values that are within the regions and outside the measurement sites. For example, the mapping may be applied on the pixels outside the measurement sites to provide estimated measurement values. The relationship between the measurement results of the measurement sites and the pixels of the measurement sites may be used to verify the estimated measurement values and/or to test the estimated measurement values and/or to fine tune the estimated measurement values.

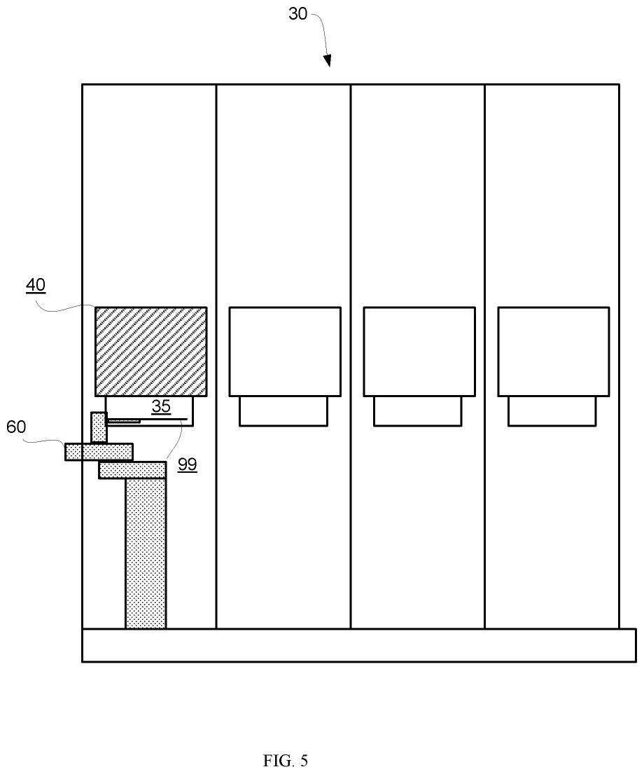

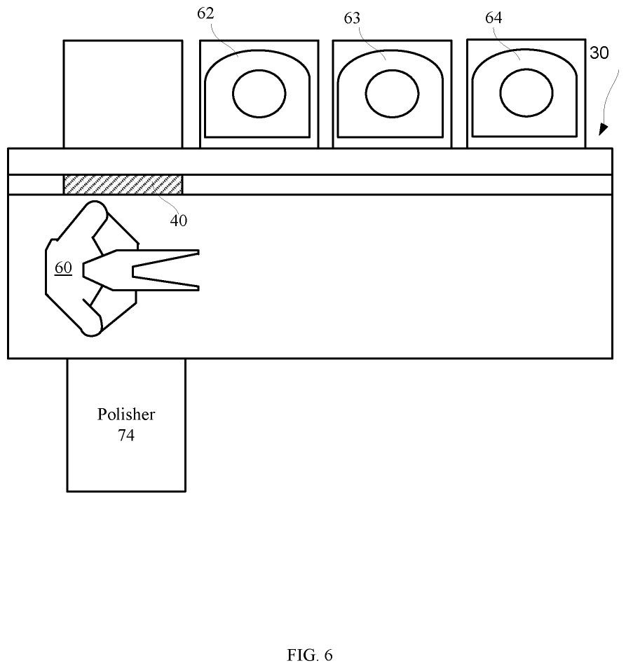

FIGS. 5 and 6 illustrate an example of a metrology system 40 (an example of MI module) and its environment—for example IM tool 31 that is integrated with a EFEM 30 of a processing equipment (CMP polisher)—denoted 70 in FIG. 6. Other environments may be provided—for example—another environment may not include an IM tool 31.

The environment also includes robot 60 (illustrates a holding wafer 99) and an IM module 31, (or any other high resolution optical metrology process-whereas high means higher than the process executed by optical metrology system 40) having a chamber 35 that is configured to receive wafer 99 from the robot, perform a high resolution spectral reflectometry process and then return the wafer to the robot.

The robot may place the wafer into one or more cassettes (FOUP's) 62, 63 and 64 of EFEM 30 and/or provide the wafer to another tool-such as polisher 74.

Robot 60 may be a part of EFEM and may travel inside it. The cassettes and the IM tool may be connected to EFEM via ports/openings. The IM tool is usually connected via six bolts attachment and cassettes put-on so-called load-ports supporting them. Metrology system 40 is assembled between the IM module 31 and the EFEM. The metrology system 40 may be aligned by Z-axis according to the Z-position of robot's arm (it could be configured to be adjustable partially of in whole during installation—e.g. according to the Z-position of the wafer on the robot's arm).

The optical metrology system 40 is positioned to perform the metrology when the wafer is loaded by robot 60 to the IM module 31 and/or when the wafer is unloaded from IM module 31.

The optical metrology system 40 may be an add-on system- and should be shaped and sized based on size constraints of other structural elements of its environment (e.g. configured to be installable between EFEM and IM module 31).

Metrology system 40 could be configured a “frame-like” around opening/port with optics/illumination at its top portion-connecting of IM tool to the EFEM is at least partially sealed. The metrology system 40 could be connectable to the IM module 31 control unit/computer(s) or additional Separate Control unit/computing of the metrology system 40 may be accommodated within or outside IM tool.

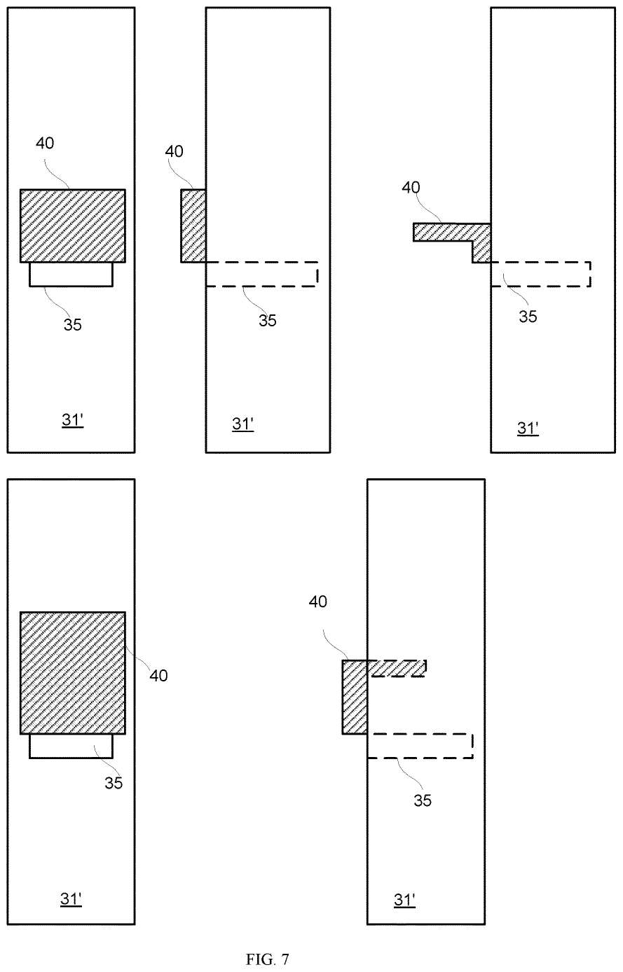

FIG. 7 illustrates examples of front views and side views of metrology system 40, the spectral reflectometry tool 31′ (an example of an IIU module) and its chamber 35. The metrology system 40 is compact—may have dimensions (width and/or height and/or depth and/or extend outside the spectral reflectometry tool) by much less than one meter. For example—the metrology system 40 may extend outside the spectral reflectometry tool by 5-15 centimeters (or more), have a width and height of about 25-45 centimeter, and the like. In some of the examples of FIG. 4—at least a part of the metrology system 40 is located within the spectral reflectometry tool 31′.

The spectral reflectometry tool 31′ may further process the outcome of the metrology system 40 for various purposes—for example calibration, verification, selection of sites to be evaluated (where outcome of the metrology system 40 may indicate a presence of problem, a deviation from spec, and the like).

In the foregoing detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarding the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

The invention may also be implemented in a computer program for running on a computer system, at least including code portions for performing steps of a method according to the invention when run on a programmable apparatus, such as a computer system or enabling a programmable apparatus to perform functions of a device or system according to the invention. The computer program may cause the storage system to allocate disk drives to disk drive groups.

A computer program is a list of instructions such as a particular application program and/or an operating system. The computer program may for instance include one or more of: a subroutine, a function, a procedure, an object method, an object implementation, an executable application, an applet, a servlet, a source code, an object code, a shared library/dynamic load library and/or other sequence of instructions designed for execution on a computer system.

The computer program may be stored internally on a non-transitory computer readable medium. All or some of the computer programs may be provided on computer readable media permanently, removably or remotely coupled to an information processing system. The computer readable media may include, for example and without limitation, any number of the following: magnetic storage media including disk and tape storage media; optical storage media such as compact disk media (e.g., CD-ROM, CD-R, etc.) and digital video disk storage media; nonvolatile memory storage media including semiconductor-based memory units such as flash memory, EEPROM, EPROM, ROM; ferromagnetic digital memories; MRAM; volatile storage media including registers, buffers or caches, main memory, RAM, etc.

A computer process typically includes an executing (running) program or portion of a program, current program values and state information, and the resources used by the operating system to manage the execution of the process. An operating system (OS) is the software that manages the sharing of the resources of a computer and provides programmers with an interface used to access those resources. An operating system processes system data and user input and responds by allocating and managing tasks and internal system resources as a service to users and programs of the system.

The computer system may for instance include at least one processing unit, associated memory and a number of input/output (I/O) devices. When executing the computer program, the computer system processes information according to the computer program and produces resultant output information via I/O devices.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above-described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also, for example, in one embodiment, the illustrated examples may be implemented as circuitry located on a single integrated circuit or within the same device. Alternatively, the examples may be implemented as any number of separate integrated circuits or separate devices interconnected with each other in a suitable manner.

Also, for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. An integrated evaluation system, comprising:
an integrated metrology (IM) head;
an integrated imaging unit (IIU) head;
a motion system configured to introduce a relative movement between a sample, and at least one head of the IM head or the IIU head; and
a processing circuit;
wherein the IM head is configured to perform measurements of a group of measurement sites of the sample;
wherein the IIU head is configured to acquire images of regions of the sample that comprises the measurement sites; wherein an aggregate area of the regions of the samples exceeds an aggregate area of the measurement sites;
wherein the processing circuit is configured to:
(i) receive the measurements of the group and the images of the regions; and
(ii) using a mapping between the measurements and the pixels of the images that correspond to the measurement sites, estimate measurement values that are within the regions and outside the measurement sites.

2. The integrated evaluation system according to claim 1, configured to perform a first measurement session and a second measurement session;
wherein during the first measurement session, the IM head is configured to perform measurements of first measurement sites of the group that are located within a first part of the sample, and the IIU head is configured to acquire images of second regions located within a second part of the sample;
wherein during the second measurement session: the IM head is configured to perform measurements of second measurement sites of the group that are located within the second part of the sample, and the IIU head is configured to acquire images of first regions located within the first part of the sample;
wherein the motion system configured to introduce the relative movement between an end of the first measurement session and a start of the second measurement session.

3. The integrated evaluation system according to claim 2, wherein the movement is a rotational movement.

4. The integrated evaluation system according to claim 2, wherein the movement is a combination of a rotational movement and another movement.

5. The integrated evaluation system according to claim 1, wherein the motion system is configured to introduce relative movement between the sample, the IM head and the IIU head, while maintaining a spatial relationship between the IM head and the IIU head.

6. The integrated evaluation system according to claim 1, wherein the motion system is configured to move, at different points of time, different heads of the IM head and the IIU head in relation to the sample.

7. The integrated evaluation system according to claim 1, wherein the motion system is configured to:
move, at a first point of time, only one head of the IM head and the IIU head in relation to the sample; and
move, at a second point of time, both the IM head and the IIU head.

8. The integrated evaluation system according to claim 1, wherein the regions of the sample cover an entirety of the sample.

9. The integrated evaluation system according to claim 1, wherein the IM head is configured to perform the measurements of the group independently from the acquisition of the images of the regions by the IIU head.

10. The integrated evaluation system according to claim 1, wherein the processing circuit is configured to determine the regions based on the measurements of the group, and the IIU head is configured to acquire the images of the regions following the determination of the regions.

11. The integrated evaluation system according to claim 1, wherein the processing circuit is configured to determine the measurement sites based on the images of the regions, and the IM head is configured to perform the measurements of the group following the determination of the regions.

12. The integrated evaluation system according to claim 1, wherein the processing circuit is configured to determine additional measurement sites, based on the images of the regions and the measurement sites, and wherein the IM head is configured to perform the measurements of the additional measurement sites following the determination of the additional measurement sites.

13. The integrated evaluation system according to claim 1, wherein the processing circuit is configured to apply a machine learning process to estimate measurement values that are within the regions and outside the measurement sites.

14. The integrated evaluation system according to claim 1, wherein the measurements of the group of measurement sites of the sample are optical critical dimension measurements.

15. A non-transitory computer readable medium that stores instructions that once executed by an integrated evaluation system causes the integrated evaluation system to:
introduce, by a motion system of the integrated evaluation system, a relative movement between a sample, and at least one head of an integrated metrology (IM) head of integrated evaluation system or an integrated imaging unit (IIU) head integrated evaluation system;
perform, by the IM head, measurements of a group of measurement sites of the sample;
acquire, by the IIU head, images of regions of the sample that comprises the measurement sites; wherein an aggregate area of the regions of the samples exceeds an aggregate area of the measurement sites;
receive, by a processing circuit of integrated evaluation system, the measurements of the group and the images of the regions; and
use a mapping between the measurements and the pixels of the images that correspond to the measurement sites, to estimate measurement values that are within the regions and outside the measurement sites.

16. The non-transitory computer readable medium according to claim 15 that stores instructions for determining by the processing circuit additional measurement sites, based on the images of the regions and the measurement sites, and performing by the IM head the measurements of the additional measurement sites following the determination of the additional measurement sites.

17. A method for operating an integrated evaluation system, the method comprising:
introducing, by a motion system of the integrated evaluation system, a relative movement between a sample, and at least one head of an integrated metrology (IM) head of the integrated evaluation system or an integrated imaging unit (IIU) head of the integrated evaluation system;
performing by the IM head, measurements of a group of measurement sites of the sample;
acquiring, by the IIU head, images of regions of the sample that comprises the measurement sites; wherein an aggregate area of the regions of the samples exceeds an aggregate area of the measurement sites;
receiving, by a processing circuit of the integrated evaluation system, the measurements of the group and the images of the regions; and
using a mapping between the measurements and the pixels of the images that correspond to the measurement sites, to estimate measurement values that are within the regions and outside the measurement sites.

18. The method according to claim 17, comprising determining, by the processing circuit, the regions based on the measurements of the group, and acquiring by the IIU head the images of the regions following the determination of the regions.

19. The method according to claim 17, comprising determining by the processing circuit the measurement sites based on the images of the regions, and performing by the IM head the measurements of the group following the determination of the regions.

20. The method according to claim 17, comprising determining by the processing circuit additional measurement sites, based on the images of the regions and the measurement sites, and performing by the IM head the measurements of the additional measurement sites following the determination of the additional measurement sites.
